(19) United States
(12) Patent Application Publication
(10) Pub. No.: US 2023/0006123 A1
(43) Pub. Date: Jan. 5, 2023

(54) THERMOELECTRIC MODULE AND OPTICAL MODULE

(71) Applicant: KELK Ltd., Kanagawa (JP)

(72) Inventors: Takaaki OHTA, Kanagawa (JP); Tetsushi TANAKA, Kanagawa (JP); Hiroyuki MATSUNAMI, Kanagawa (JP); Haruka KOREEDA, Kanagawa (JP)

(21) Appl. No.: 17/781,526

(22) PCT Filed: Nov. 16, 2020
(86) PCT No.: PCT/JP2020/042601

§ 371 Date: Jun. 1, 2022

(30) Foreign Application Priority Data
Dec. 19, 2019 (JP) 2019-229191
Dec. 19, 2019 (JP) 2019-229192

(51) Int. Cl. H01L 35/32; H01L 35/10; H01S 5/024

(52) U.S. Cl. CPC H01L 35/32; H01L 35/10; H01S 5/02415

(57) ABSTRACT

A thermoelectric module includes a substrate; a thermoelectric element; a bonding portion including an electrode that bonds the substrate and the thermoelectric element; an organic material film that covers a front surface of the bonding portion; and an inorganic material film that covers the organic material film.

### FIELD

The present disclosure relates to a thermoelectric module and an optical module.

### BACKGROUND

A thermoelectric module that absorbs heat or generates heat by the Peltier effect is known. In a case where a thermoelectric element of the thermoelectric module is energized, the thermoelectric module absorbs heat or generates heat. In a case where the thermoelectric module in a dew condensation state is energized, electrochemical migration is likely to occur, and an electrical short circuit or an electrical disconnection due to movement of a metal is likely to occur. Patent Literature 1 discloses a technique for forming an airtight barrier layer so as to cover a thermoelectric element using atomic layer deposition (ALD). Patent Literature 2 discloses a thermoelectric module including a seal member that seals a space between a substrate for heat absorption and a substrate for heat dissipation.

### CITATION LIST

### Patent Literature

Patent Literature 1: JP 2014-504331 A Patent Literature 2: JP 2005-303183 A

### SUMMARY

### Technical Problem

By covering the thermoelectric element with an inorganic material film, dew condensation of the thermoelectric element may be prevented. However, since the inorganic material film is brittle, in a case where irregularities are present on a front surface of an object on which the inorganic material film is to be provided, a crack is highly likely to occur in the inorganic material film. In a case where a crack occurs in the inorganic material film, it is difficult to sufficiently prevent dew condensation of the thermoelectric element, and as a result, electrochemical migration is likely to occur.

By sealing a space between a substrate for heat absorption and a substrate for heat dissipation with a seal member, dew condensation of the thermoelectric element may be prevented. However, in a case where the seal member is made of only an epoxy resin, dew condensation of the thermoelectric element may not be sufficiently prevented. In a case where dew condensation of the thermoelectric element is not sufficiently prevented, electrochemical migration may occur.

An object of the present disclosure is to provide a thermoelectric module capable of preventing an occurrence of an electrical short circuit or an electrical disconnection.

### Solution to Problem

According to an aspect of the present invention, a thermoelectric module comprises: a substrate; a thermoelectric element; a bonding portion including an electrode that bonds the substrate and the thermoelectric element; an organic material film that covers a front surface of the bonding portion; and an inorganic material film that covers the organic material film.

According to another aspect of the present invention, a thermoelectric module comprises: a pair of substrates; a thermoelectric element disposed between the pair of substrates; a base film that is connected to circumferential line portions of the substrates and seals a space between the pair of substrates; and an inorganic material film that covers a front surface of the base film.

### ADVANTAGEOUS EFFECTS OF INVENTION

According to the present disclosure, there is provided a thermoelectric module capable of preventing an occurrence of an electrical short circuit or an electrical disconnection.

### BRIEF DESCRIPTION OF DRAWINGS

FIG. 1 is a sectional view illustrating an optical module according to a first embodiment.

FIG. 2 is a sectional view illustrating a thermoelectric module according to the first embodiment.

FIG. 3 is an enlarged sectional view illustrating a part of the thermoelectric module according to the first embodiment.

FIG. 4 is a flowchart illustrating a method for manufacturing the thermoelectric module according to the first embodiment.

FIG. 5 is a diagram illustrating a performance test result of the thermoelectric module according to the first embodiment.

FIG. 6 is a sectional view illustrating the thermoelectric module according to a second embodiment.

FIG. 7 is a flowchart illustrating a method for manufacturing the thermoelectric module according to the second embodiment.

FIG. 8 is a diagram illustrating a performance test result of the thermoelectric module according to the second embodiment.

FIG. 9 is a sectional view illustrating a first modification example of the thermoelectric module according to the second embodiment.

FIG. 10 is a sectional view illustrating a second modification example of the thermoelectric module according to the second embodiment.

FIG. 11 is a sectional view illustrating a third modification example of the thermoelectric module according to the second embodiment.

### DESCRIPTION OF EMBODIMENTS

Hereinafter, embodiments according to the present disclosure will be described with reference to the drawings, and the present disclosure is not limited thereto. Components of a plurality of embodiments to be described below may be appropriately combined. In addition, some components may not be used.

In the following description, an XYZ orthogonal coordinate system is set, and positional relationships between respective portions will be described with reference to the XYZ orthogonal coordinate system. A direction parallel to an X axis in a predetermined plane is defined as an X axis direction, a direction parallel to a Y axis orthogonal to the X axis in the predetermined plane is defined as a Y axis direction, and a direction parallel to a Z axis orthogonal to the predetermined plane is defined as a Z axis direction. The X axis, the Y axis, and the Z axis are orthogonal to each other. Further, a plane including the X axis and the Y axis is defined as an XY plane, a plane including the Y axis and the Z axis is defined as a YZ plane, and a plane including the Z axis and the X axis is defined as an XZ plane. The XY plane is parallel to the predetermined plane. The XY plane, the YZ plane, and the XZ plane are orthogonal to each other.

### First Embodiment

A first embodiment will be described.

### Optical Module

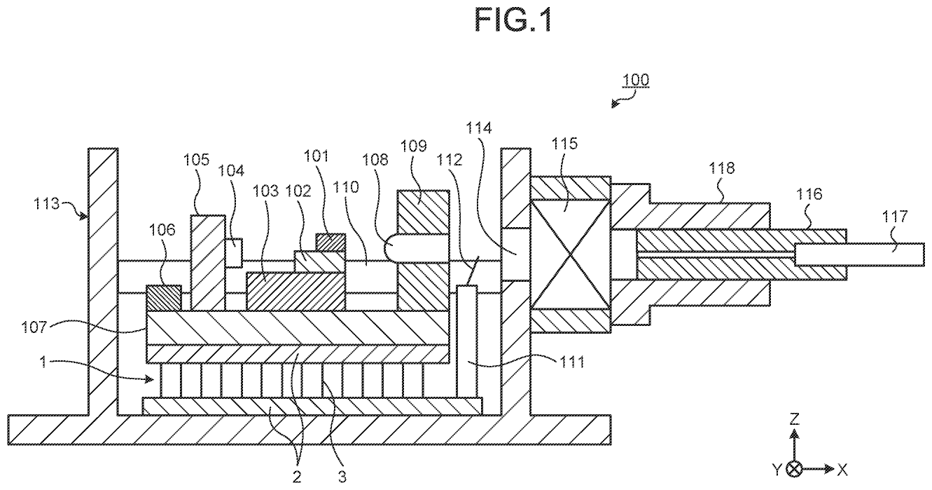

FIG. 1 is a sectional view illustrating an optical module 100 according to an embodiment. The optical module 100 is used for, for example, optical communication. As illustrated in FIG. 1, the optical module 100 includes a thermoelectric module 1, a light emitting element 101, a heat sink 102, a first header 103, a light receiving element 104, a second header 105, a temperature sensor 106, a metal plate 107, a lens 108, a lens holder 109, a first terminal 110, a second terminal 111, a wire 112, and a housing 113.

Further, the optical module 100 includes an optical isolator 115, an optical ferrule 116, an optical fiber 117, and a sleeve 118.

The thermoelectric module 1 absorbs heat or generates heat by the Peltier effect. The thermoelectric module 1 includes a pair of substrates 2 and thermoelectric elements 3 disposed between the pair of substrates 2.

The light emitting element 101 emits light. The light emitting element 101 includes, for example, a laser diode that emits laser light. The heat sink 102 supports the light emitting element 101. The heat sink 102 dissipates heat generated by the light emitting element 101. The first header 103 supports the heat sink 102. The heat sink 102 is fixed to the first header 103.

The light receiving element 104 detects light generated from the light emitting element 101. The light receiving element 104 includes, for example, a photodiode. The second header 105 supports the light receiving element 104. The light receiving element 104 is fixed to the second header 105.

The temperature sensor 106 detects a temperature of the metal plate 107. The temperature sensor 106 includes, for example, a thermistor.

The metal plate 107 supports the first header 103, the second header 105, and the temperature sensor 106. The first header 103, the second header 105, and the temperature sensor 106 are fixed to the metal plate 107 by soldering.

The lens 108 collects the light emitted from the light emitting element 101. The lens holder 109 holds the lens 108.

The first terminal 110 is connected to the first header 103, the second header 105, and the temperature sensor 106. The second terminal 111 is connected to the thermoelectric module 1. The first terminal 110 and the second terminal 111 are connected to each other via the wire 112.

The housing 113 accommodates the thermoelectric module 1, the light emitting element 101, the heat sink 102, the first header 103, the light receiving element 104, the second header 105, the temperature sensor 106, the metal plate 107, the lens 108, the lens holder 109, the first terminal 110, the second terminal 111, and the wire 112. The housing 113 includes an opening 114 through which the light emitted from the light emitting element 101 passes.

The optical isolator 115 is disposed outside the housing 113 so as to close the opening 114. The optical isolator 115 allows light traveling in one direction to pass through the optical isolator 115, and blocks light traveling in an opposite direction. The light emitted from the light emitting element 101 and passing through the lens 108 enters the optical isolator 115 via the opening 114. The light having entered the optical isolator 115 passes through the optical isolator 115.

The optical ferrule 116 guides the light emitted from the optical isolator 115 to the optical fiber 117. The sleeve 118 supports the optical ferrule 116.

Next, an operation of the optical module 100 will be described. The light emitted from the light emitting element 101 is collected by the lens 108, and then enters the optical isolator 115 via the opening 114. The light having entered the optical isolator 115 passes through the optical isolator 115, and then enters an end surface of the optical fiber 117 via the optical ferrule 116.

At least a part of the light emitted from the light emitting element 101 is emitted toward the light receiving element 104. The light receiving element 104 receives the light emitted from the light emitting element 101. A light emitting state of the light emitting element 101 is monitored by the light receiving element 104.

The heat generated from the light emitting element 101 is transmitted to the metal plate 107 via the heat sink 102 and the first header 103. The temperature sensor 106 detects a temperature of the metal plate 107. In a case where the temperature sensor 106 detects that the temperature of the metal plate 107 reaches a specified temperature, a current is supplied to the thermoelectric module 1. In a case where the thermoelectric elements 3 of the thermoelectric module 1 are energized, the thermoelectric module 1 absorbs the heat by the Peltier effect. Thereby, the light emitting element 101 is cooled. The temperature of the light emitting element 101 is adjusted by the thermoelectric module 1.

### Thermoelectric Module

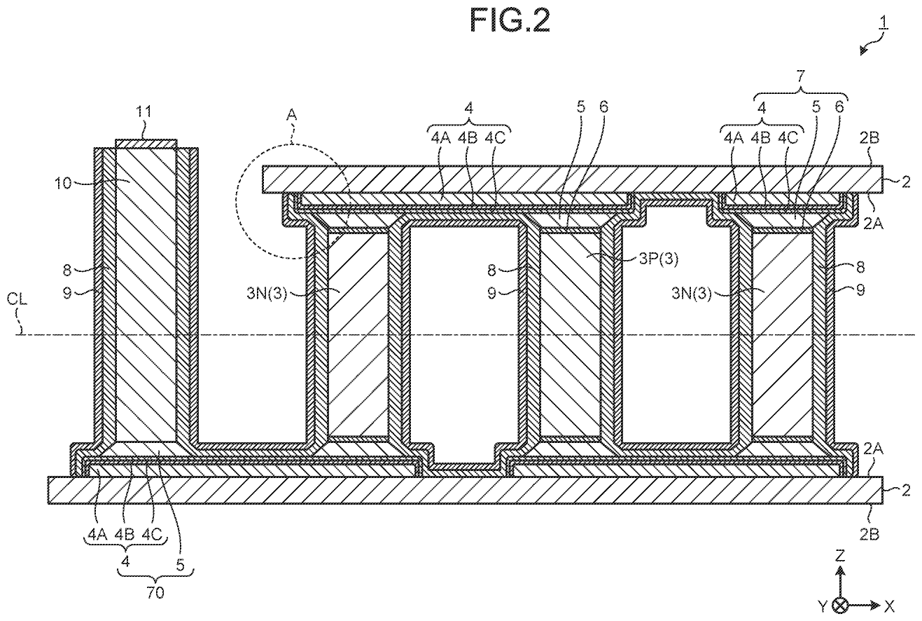

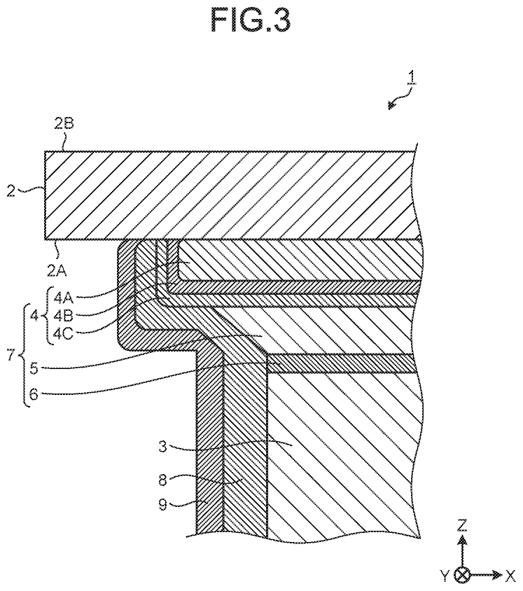

FIG. 2 is a sectional view illustrating the thermoelectric module 1 according to the embodiment. FIG. 3 is an enlarged sectional view illustrating a part of the thermoelectric module 1 according to the present embodiment. FIG. 3 corresponds to an enlarged view of a portion A in FIG. 2.

The thermoelectric module 1 includes a pair of substrates 2, thermoelectric elements 3 disposed between the pair of substrates 2, a bonding portion 7 that bonds the substrate 2 and the thermoelectric element 3, an organic material film 8 that covers a front surface of the bonding portion 7, and an inorganic material film 9 that covers the organic material film 8. The one substrate 2 is a substrate for heat absorption. The other substrate 2 is a substrate for heat dissipation.

The thermoelectric module 1 has a substantially symmetrical structure in the Z axis direction. In the following description, a structure of the thermoelectric module 1 from a symmetry line CL illustrated in FIG. 2 toward a +Z direction will be mainly described.

The substrate 2 is formed of an electrical insulation material. In the embodiment, the substrate 2 is a ceramic substrate. The substrate 2 is formed of an oxide ceramic or a nitride ceramic. Examples of the oxide ceramic include aluminum oxide (Al₂O₃) and zirconium oxide (ZrO₂). Examples of the nitride ceramic include silicon nitride (Si₃N₄) and aluminum nitride (AlN).

The substrate 2 has a first surface 2A and a second surface 2B. The first surface 2A faces a space between the pair of substrates 2. That is, the first surface 2A faces a space where the thermoelectric elements 3 are present. The second surface 2B faces an opposite direction to the first surface 2A. Each of the first surface 2A and the second surface 2B is substantially parallel to the XY plane.

The thermoelectric elements 3 are formed of a thermoelectric material such as a bismuth-tellurium-based compound (Bi—Te). The thermoelectric elements 3 includes a first thermoelectric element 3N that is an n-type thermoelectric semiconductor element and a second thermoelectric element 3P that is a p-type thermoelectric semiconductor element. A plurality of first thermoelectric elements 3N and a plurality of second thermoelectric elements 3P are disposed in the XY plane. The first thermoelectric elements 3N and the second thermoelectric elements 3P are alternately disposed in the X axis direction. The first thermoelectric elements 3N and the second thermoelectric elements 3P are alternately disposed in the Y axis direction.

Examples of the thermoelectric material for forming the thermoelectric element 3 include bismuth (Bi), a bismuth-tellurium-based compound (Bi—Te), a bismuth-antimony-based compound (Bi—Sb), a lead-tellurium-based compound (Pb—Te), a cobalt-antimony-based compound (Co—Sb), an iridium-antimony-based compound (Ir—Sb), a cobalt-arsenic-based compound (Co—As), a silicon-germanium-based compound (Si—Ge), a copper-selenium-based compound (Cu—Se), a gadolium-selenium-based compound (Gd—Se), a boron-carbide-based compound, a tellurium-based perovskite oxide, a rare earth sulfide, a TAGS-based compound (GeTe—AgSbTe₂), and a Heusler substance such as TiNiSn, FeNbSb, and TiCoSb.

The bonding portion 7 bonds the first surface 2A of the substrate 2 to an end surface of the thermoelectric element 3. The bonding portion 7 is a metal bonding portion containing metal. The bonding portion 7 includes an electrode 4, a bonding layer 5, and a diffusion prevention layer 6. In the embodiment, the electrode 4 is disposed so as to be in contact with the first surface 2A of the substrate 2. The diffusion prevention layer 6 is disposed between the electrode 4 and the thermoelectric element 3. In the embodiment, the diffusion prevention layer 6 is disposed so as to be in contact with the end surface of the thermoelectric element 3. The bonding layer 5 is disposed between the electrode 4 and the diffusion prevention layer 6.

The electrode 4 supplies power to the thermoelectric element 3. A plurality of electrodes 4 are provided on the first surface 2A. The electrode 4 is connected to each of the pair of the first thermoelectric element 3N and the second thermoelectric element 3P which are adjacent to each other. The electrode 4 is connected to the thermoelectric element 3 via the bonding layer 5 and the diffusion prevention layer 6.

The electrode 4 includes a first electrode layer 4A in contact with the first surface 2A, a second electrode layer 4B that covers the first electrode layer 4A, and a third electrode layer 4C that covers the second electrode layer 4B.

The first electrode layer 4A is formed of copper (Cu). The second electrode layer 4B is formed of nickel (Ni). The third electrode layer 4C is formed of gold (Au). An intermediate electrode layer may be disposed between the second electrode layer 4B and the third electrode layer 4C. Examples of a material for forming the intermediate electrode layer include palladium (Pd).

The bonding layer 5 bonds the electrode 4 and the diffusion prevention layer 6. Examples of a material for forming the bonding layer 5 include lead-free solder containing tin (Sn) as a main component. The lead-free solder means solder having a lead content of 0.10% by mass or less. Examples of a solder material for forming the bonding layer 5 include tin-antimony-alloy-based (Sn—Sb-based) solder which is an intermetallic compound of tin (Sn) and antimony (Sb), gold-tin-alloy-based (Au—Sn-based) solder which is an intermetallic compound of gold (Au) and tin (Sn), and copper-tin-alloy-based (Cu—Sn-based) solder which is an intermetallic compound of copper (Cu) and tin (Sn).

That is, in the present embodiment, the electrode 4 and the diffusion prevention layer 6 are bonded to each other by solder. The diffusion prevention layer 6 is connected to the electrode 4 via the bonding layer 5. The diffusion prevention layer 6 is in contact with the bonding layer 5. The electrode 4 is in contact with the bonding layer 5. In the embodiment, the third electrode layer 4C of the electrode 4 is in contact with the bonding layer 5.

The diffusion prevention layer 6 prevents elements included in the bonding layer 5 from diffusing into the thermoelectric element 3. In the embodiment, the diffusion prevention layer 6 is formed of nickel (Ni). The elements included in the bonding layer 5 are prevented from diffusing into the thermoelectric element 3, and thus a degradation in performance of the thermoelectric element 3 is prevented.

The third electrode layer 4C is bonded to the diffusion prevention layer 6 by the bonding layer 5 which is solder. The third electrode layer 4C is formed of gold (Au) which is easily bonded to the diffusion prevention layer 6 by soldering. The second electrode layer 4B functions as a diffusion prevention layer that prevents elements included in the first electrode layer 4A from diffusing into the third electrode layer 4C. The second electrode layer 4B is provided so as to cover the first electrode layer 4A. The elements included in the first electrode layer 4A are prevented from diffusing into the third electrode layer 4C, and thus the third electrode layer 4C and the diffusion prevention layer 6 are sufficiently connected to each other via the bonding layer 5.

The organic material film 8 is a film made of an organic material. In the embodiment, the organic material film 8 is made of polyparaxylylene. The organic material film 8 may be a film containing polyparaxylylene as a main component. The organic material film 8 may be made of a mixed material of polyparaxylylene and another organic material.

The organic material film 8 is disposed so as to cover the front surface of the bonding portion 7. In the embodiment, the organic material film 8 is disposed so as to cover not only the front surface of the bonding portion 7 but also a front surface of the thermoelectric element 3. The organic material film 8 is disposed so as to cover the first surface 2A of the substrate 2.

In the embodiment, an adhesive layer made of a silane coupling agent is disposed between the front surface of the bonding portion 7 and the organic material film 8. The organic material film 8 is disposed on the front surface of the bonding portion 7 via the adhesive layer. The adhesive layer firmly adheres the organic material film 8 to the front surface of the bonding portion 7. Similarly, an adhesive layer made of a silane coupling agent is disposed between the front surface of the thermoelectric element 3 and the organic material film 8 and between the first surface 2A of the substrate 2 and the organic material film 8.

The organic material film 8 is a smooth film. A front surface of the organic material film 8 is smoother than the front surface of the bonding portion 7. That is, a front surface roughness of the organic material film 8 is lower than a front surface roughness of the bonding portion 7. The front surface of the organic material film 8 is smoother than the front surface of the thermoelectric element 3. That is, the front surface roughness of the organic material film 8 is lower than a front surface roughness of the thermoelectric element 3. The front surface of the organic material film 8 is smoother than the first surface 2A of the substrate 2. That is, the front surface roughness of the organic material film 8 is lower than a front surface roughness of the substrate 2.

The organic material film 8 may have a water vapor barrier property (moisture-proof property). That is, the organic material film 8 may have a function of preventing dew condensation of the bonding portion 7 and dew condensation of the thermoelectric element 3.

The inorganic material film 9 is a film made of an inorganic material. In the embodiment, the inorganic material film 9 is made of silicon dioxide (SiO₂). The inorganic material film 9 may be a film containing silicon dioxide as a main component. The inorganic material film 9 may be made of a mixed material of silicon dioxide and another inorganic material.

The inorganic material film 9 is disposed so as to cover the front surface of the organic material film 8. The inorganic material film 9 is disposed so as to cover the organic material film 8 that covers the front surface of the bonding portion 7. In the embodiment, the inorganic material film 9 is disposed so as to cover not only the organic material film 8 that covers the front surface of the bonding portion 7 but also the organic material film 8 that covers the front surface of the thermoelectric element 3. Further, the inorganic material film 9 is disposed so as to cover the organic material film 8 that covers the first surface 2A of the substrate 2.

The inorganic material film 9 is a water vapor barrier film (moisture-proof film) having a water vapor barrier property (moisture-proof property). The inorganic material film 9 prevents dew condensation of the bonding portion 7. In the embodiment, the inorganic material film 9 prevents not only dew condensation of the bonding portion 7 but also dew condensation of the thermoelectric element 3.

As described above, the front surface of the organic material film 8 is smooth. Therefore, the inorganic material film 9 is stably formed on the front surface of the organic material film 8.

A thickness of the inorganic material film 9 is thinner than a thickness of the organic material film 8. In the embodiment, the thickness of the organic material film 8 is approximately 10 [μm]. The thickness of the inorganic material film 9 is approximately equal to or thicker than 0.01 [μm] and equal to or thinner than 1.10 [μm]. As the thickness of the inorganic material film 9 is thicker, the water vapor barrier property of the inorganic material film 9 is improved. In a case where the thickness of the inorganic material film 9 is too thick, a crack is likely to occur in the inorganic material film 9. Therefore, the thickness of the inorganic material film 9 is set based on a required water vapor barrier property and a required crack resistance.

As illustrated in FIG. 2, the thermoelectric module 1 includes a post 10 on which a post electrode 11 is disposed. The post 10 has a columnar shape. A material of the post 10 is nickel (Ni). A material of the post electrode 11 is gold (Au). The post 10 is bonded to the substrate 2 via a bonding portion 70 (second bonding portion). The bonding portion 70 includes an electrode 4 and a bonding layer 5. The bonding portion 70 does not include a diffusion prevention layer 6.

A front surface of the bonding portion 70 between the post 10 and the substrate 2 is covered with the organic material film 8 and the inorganic material film 9. The organic material film 8 covers the front surface of the bonding portion 70 between the post 10 and the substrate 2. The inorganic material film 9 covers the organic material film 8 that covers the front surface of the bonding portion 70 between the post 10 and the substrate 2.

A front surface of the post 10 is covered with the organic material film 8 and the inorganic material film 9. The organic material film 8 covers the front surface of the post 10. The inorganic material film 9 covers the organic material film 8 that covers the front surface of the post 10.

In the example illustrated in FIG. 2, the post 10 is bonded to the first surface 2A of the substrate 2, which is provided in a −Z direction, from the pair of substrates 2 via the bonding portion 70.

The post electrode 11 is disposed at an end portion of the post 10 in the +Z direction.

A plurality of posts 10 are provided at intervals. For example, two posts 10 are provided.

### Method for Manufacturing Thermoelectric Module

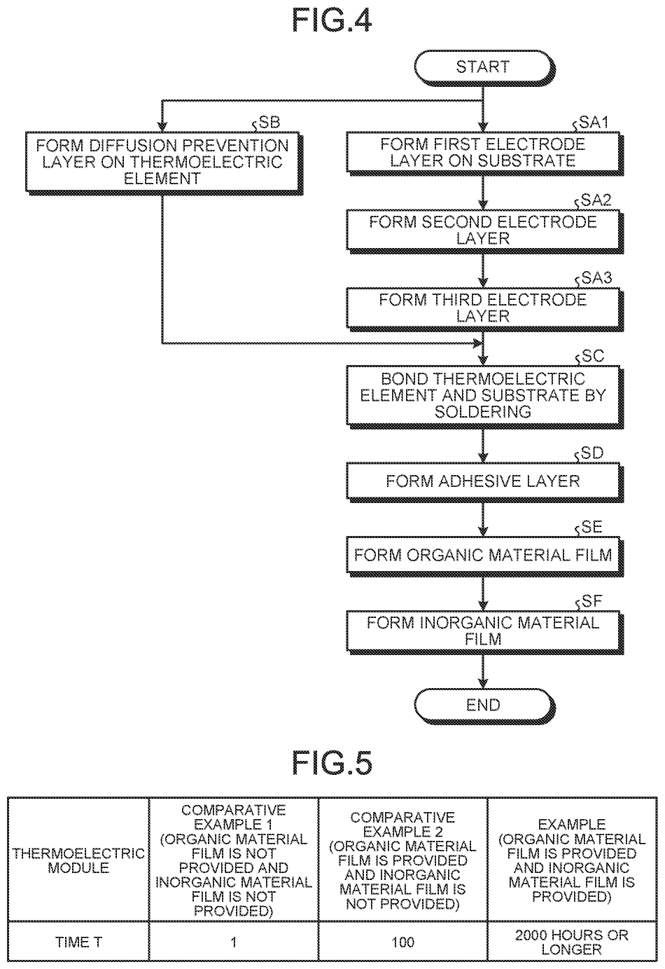

FIG. 4 is a flowchart illustrating a method for manufacturing the thermoelectric module 1 according to the embodiment. As the substrate 2, for example, a substrate made of aluminum nitride (AlN) or aluminum oxide (Al₂O₃) may be used. The first electrode layer 4A made of copper (Cu) is formed on the first surface 2A of the substrate 2. For example, the first electrode layer 4A is formed by plating (step SA1).

Next, the second electrode layer 4B made of nickel (Ni) is formed so as to cover the first electrode layer 4A. For example, the second electrode layer 4B is formed by plating (step SA2).

Next, the third electrode layer 4C made of gold (Au) is formed so as to cover the second electrode layer 4B. For example, the third electrode layer 4C is formed by plating (step SA3).

As described above, an intermediate electrode layer made of palladium (Pd) may be formed between the second electrode layer 4B and the third electrode layer 4C.

The diffusion prevention layer 6 made of nickel (Ni) is formed on the end surface of the thermoelectric element 3. As the thermoelectric element 3, the thermoelectric element 3 made of, for example, a bismuth-tellurium-based compound (Bi—Te) may be used. For example, the diffusion prevention layer 6 is formed by a sputtering method (step SB).

The third electrode layer 4C of the substrate 2 after completion of processing of step SA3 and the diffusion prevention layer 6 of the thermoelectric element 3 after completion of processing of step SB are bonded to each other by the bonding layer 5 which is solder (step SC).

As the bonding layer 5, for example, gold-tin-alloy-based (Au—Sn-based) solder may be used. The substrate 2 and the thermoelectric element 3 are bonded to each other by processing of step SC by the bonding portion 7. The bonding portion 7 includes the electrode 4, the bonding layer 5, and the diffusion prevention layer 6.

Next, a silane coupling agent is applied to the front surface of the bonding portion 7 and the front surface of the thermoelectric element 3. An adhesive layer is formed by the silane coupling agent (step SD).

As the silane coupling agent, for example, “AdPro Poly” manufactured by Parylene Japan LLC may be used.

Next, the organic material film 8 is formed so as to cover the front surface of the bonding portion 7 and the front surface of the thermoelectric element 3 (step SE).

For example, the organic material film 8 is formed by vapor deposition polymerization. As the polyparaxylylene for forming the organic material film 8, for example, “Parylene HT” manufactured by Parylene Japan LLC may be used. The thickness of the organic material film 8 is, for example, 10 [μm].

Next, the inorganic material film 9 is formed so as to cover the front surface of the organic material film 8 (step SF).

For example, the inorganic material film 9 is formed by atomic layer deposition (ALD). The thickness of the inorganic material film 9 is, for example, 0.04 [μm]. The thickness of the inorganic material film 9 may be 0.09 [μm] or 0.14 [μm].

The method for forming the inorganic material film 9 may not be atomic layer deposition, and may be, for example, sputtering, vapor deposition, or chemical vapor deposition (CVD). Preferably, the method for forming the inorganic material film 9 is atomic layer deposition or chemical vapor deposition. According to atomic layer deposition or chemical vapor deposition, even in a case where a front surface of a film to be coated has a complicated shape, it is possible to sufficiently form the film. According to atomic layer deposition, it is possible to form a film at a low temperature as compared with chemical vapor deposition. Thus, atomic layer deposition is excellent in film thickness uniformity and coverage (step coverage) as compared with chemical vapor deposition. Therefore, as the method for forming the inorganic material film 9, preferably, atomic layer deposition is used. Further, in atomic layer deposition, preferably, room-temperature atomic layer deposition (room-temperature ALD) is used. According to room-temperature ALD, it is possible to form a film at room temperature, and thus the thermoelectric module 1 is not damaged by heat. Therefore, preferably, room-temperature ALD is used.

A film may be formed on the second surface 2B of the substrate 2. The film formed on the second surface 2B is unnecessary. For this reason, processing of removing the film formed on the second surface 2B may be performed. In the embodiment, the unnecessary film is removed by laser ablation. A laser beam used for laser ablation is a KrF excimer laser beam (wavelength of 248 [nm]), and oxygen (O₂) is used as an assist gas.

### Effects

As described above, according to the embodiment, the front surface of the bonding portion 7 made of metal is covered with the organic material film 8, and the organic material film 8 is covered with the inorganic material film 9. A front surface of the organic material film 8 is smoother than the front surface of the bonding portion 7. The inorganic material film 9 is formed on the smooth front surface of the organic material film 8, and thus an occurrence of a crack in the inorganic material film 9 is prevented. Since the bonding portion 7 is covered with the inorganic material film 9 in which an occurrence of a crack is prevented, dew condensation of the bonding portion 7 is prevented. Thus, even in a case where the bonding portion 7 is energized, an occurrence of electrochemical migration is prevented. Therefore, an occurrence of an electrical short circuit or an electrical disconnection due to movement of the metal of the bonding portion 7 is prevented. Further, a deterioration of the thermoelectric element 3 is prevented. Accordingly, performance of the thermoelectric module 1 is maintained for a long period of time.

In a case where the temperature adjusted by the thermoelectric module 1 is lower than a dew point of an ambient environment atmosphere, dew condensation is highly likely to occur on the thermoelectric module 1. For this reason, in order to prevent an occurrence of electrochemical migration, it is necessary to improve airtightness of the housing (113) and fill an internal space of the housing with an inert gas. In a configuration in which airtightness of the housing is improved and the internal space of the housing is filled with an inert gas, a cost increases. In the embodiment, the front surface of the bonding portion 7 is covered with the organic material film 8, and the front surface of the organic material film 8 is covered with the inorganic material film 9. Therefore, even though airtightness of the housing 113 is low, dew condensation of the bonding portion 7 is sufficiently prevented, and an occurrence of electrochemical migration is prevented. Accordingly, it is possible to provide the thermoelectric module 1 and the optical module 100 with reduced cost.

In the embodiment, the organic material film 8 contains polyparaxylylene. By using polyparaxylylene, the front surface of the organic material film 8 is sufficiently smoothed. Further, polyparaxylylene has a water vapor barrier property (moisture-proof property). Therefore, dew condensation of the bonding portion 7 is sufficiently prevented.

In the embodiment, the inorganic material film 9 contains silicon dioxide. By using silicon dioxide, the inorganic material film 9 can have a high water vapor barrier property (moisture-proof property). Further, thermal conductivity of silicon dioxide is low, and thus a temperature difference between one substrate 2 and the other substrate 2 is prevented from being decreased. Therefore, the Peltier effect of the thermoelectric module 1 is prevented from being reduced. Accordingly, a degradation in performance of the thermoelectric module 1 is prevented.

A thickness of the inorganic material film 9 is thinner than a thickness of the organic material film 8. As a result, an excessive increase in the thermal conductivity of the inorganic material film 9 is prevented. Thus, a temperature difference between one substrate 2 and the other substrate 2 is prevented from being decreased. Therefore, the Peltier effect of the thermoelectric module 1 is prevented from being reduced. Accordingly, a degradation in performance of the thermoelectric module 1 is prevented.

In the embodiment, the organic material film 8 covers not only the front surface of the bonding portion 7 but also the front surface of the thermoelectric element 3. Further, the inorganic material film 9 covers not only the organic material film 8 that covers the front surface of the bonding portion 7 but also the organic material film 8 that covers the front surface of the thermoelectric element 3. Accordingly, dew condensation of the thermoelectric module 1 is sufficiently prevented, and a deterioration of the thermoelectric element 3 is prevented.

### Example

FIG. 5 is a diagram illustrating a performance test result of the thermoelectric module. A performance test is performed on each of the thermoelectric module 1 according to Example that is manufactured by the above-described manufacturing method, a thermoelectric module according to Comparative Example 1 in which both the organic material film 8 and the inorganic material film 9 are not provided, and a thermoelectric module according to Comparative Example 2 in which the organic material film 8 is provided and the inorganic material film 9 is not provided.

In the performance test, in an environment of a high temperature and high humidity (temperature of 85 [° C.] and humidity of 85 [% RH]), a predetermined current is continuously supplied to each of the thermoelectric modules according to Comparative Example 1, Comparative Example 2, and Example, and a time T required until an electric resistance change rate (AR), which is a physical quantity for determining a deterioration of the thermoelectric module 1, exceeds 5 [%] is measured.

As illustrated in FIG. 5, the time T according to Comparative Example 1 is one hour, and the time T according to Comparative Example 2 is 100 hours. On the other hand, the time T according to Example is 2000 hours or longer. According to the performance test, it is confirmed that the thermoelectric module 1 according to Example can maintain performance for a long time.

### Modification Example of First Embodiment

In the above-described embodiment, the organic material film 8 and the inorganic material film 9 are provided on the first surface 2A of the substrate 2. The organic material film 8 and the inorganic material film 9 may not be provided on the first surface 2A of the substrate 2.

In the above-described embodiment, the organic material film 8 and the inorganic material film 9 are provided on the front surface of the thermoelectric element 3. The organic material film 8 and the inorganic material film 9 may not be provided on the front surface of the thermoelectric element 3. In the thermoelectric module 1, a deterioration of the bonding portion 7 is most likely to progress due to dew condensation. For this reason, the front surface of the bonding portion 7 is covered with the organic material film 8 and the inorganic material film 9, and thus progress of a deterioration of the bonding portion 7 can be prevented.

In the above-described embodiment, one organic material film 8 and one inorganic material film 9 are provided. At least one of the organic material film 8 and the inorganic material film 9 may be provided in three or more layers. By providing at least one of the organic material film 8 and the inorganic material film 9 in a plurality of layers, electrochemical migration of the metal material due to dew condensation of the thermoelectric module 1 is prevented, and a deterioration of the thermoelectric element 3 due to dew condensation is prevented.

In the above-described embodiment, the organic material film 8 is made of polyparaxylylene. The organic material film 8 may be made of, for example, polyimide resin or polytetrafluoroethylene (PTFE).

In the above-described embodiment, the inorganic material film 9 is made of silicon dioxide. The inorganic material film 9 may be made of aluminum oxide (AL₂O₃), niobium pentoxide (Nb₂O₅), silicon nitride (Si₃N₄), titanium oxide (TiO₂), or hafnium oxide (HfO₂). In particular, aluminum oxide is excellent in a moisture-proof property (water vapor barrier property).

In the above-described embodiment, the thermoelectric module 1 absorbs heat or generates heat by the Peltier effect. The thermoelectric module 1 may generate electric power by the Zeebeck effect. In a case where a temperature difference is given to the pair of substrates 2 of the thermoelectric module 1, the thermoelectric module 1 can generate electric power by the Zeebeck effect.

### Second Embodiment

A second embodiment will be described. In the following description, the same or equivalent components as the components of the above-described embodiment are denoted by the same reference numerals, and a description thereof is simplified or omitted.

### Thermoelectric Module

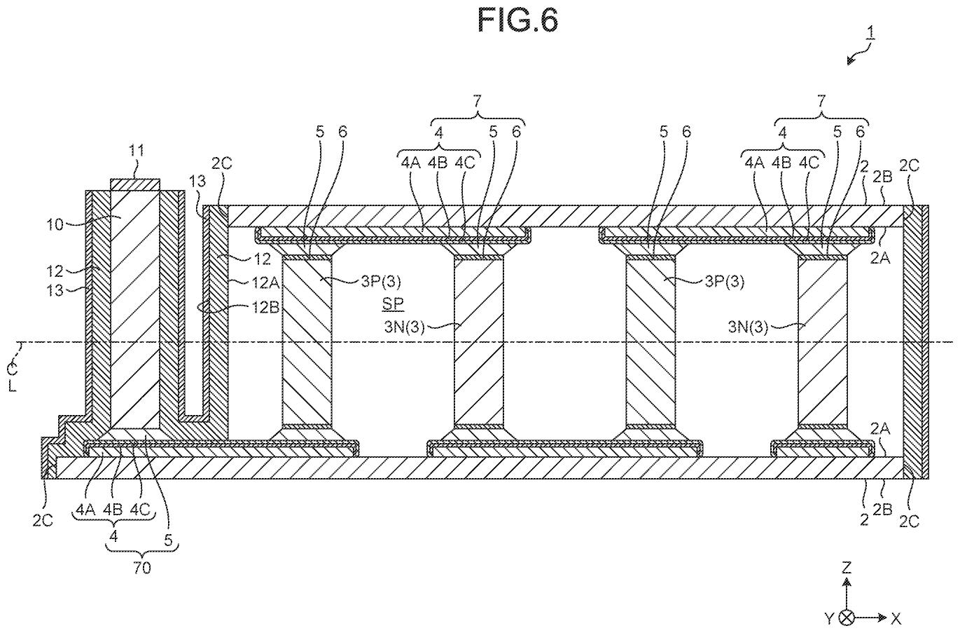

FIG. 6 is a sectional view illustrating the thermoelectric module 1 according to the embodiment.

The thermoelectric module 1 includes a pair of substrates 2, thermoelectric elements 3 disposed between the pair of substrates 2, a bonding portion 7 that bonds the substrate 2 and the thermoelectric element 3, a base film 12 that seals a space between the pair of substrates 2, and an inorganic material film 13 that covers a front surface of the base film 12. The one substrate 2 is a substrate for heat absorption. The other substrate 2 is a substrate for heat dissipation.

The thermoelectric module 1 has a substantially symmetrical structure in the Z axis direction. In the following description, a structure of the thermoelectric module 1 from a symmetry line CL illustrated in FIG. 6 toward a +Z direction will be mainly described.

The substrate 2 has a first surface 2A, a second surface 2B, and a third surface 2C. The first surface 2A faces a space SP between the pair of substrates 2. That is, the first surface 2A faces a space SP where the thermoelectric elements 3 are present. The second surface 2B faces an opposite direction to the first surface 2A. Each of the first surface 2A and the second surface 2B is substantially parallel to the XY plane. The third surface 2C connects a circumferential edge portion of the first surface 2A and a circumferential edge portion of the second surface 2B. The third surface 2C is a side surface of the substrate 2. The third surface 2C is substantially parallel to the Z axis.

The base film 12 is connected to the circumferential edge portion of each of the pair of substrates 2. In the embodiment, the base film 12 is connected to the third surface 2C of the substrate 2. The base film 12 seals a space SP between the pair of substrates 2. The space SP (internal space) of the thermoelectric module 1 in which the thermoelectric elements 3 and the bonding portions 7 are disposed is defined by the pair of substrates 2 and the base film 12. The base film 12 functions as a seal film that seals the space SP between the pair of substrates 2.

In the embodiment, the space SP in which the thermoelectric elements 3 and the bonding portions 7 are disposed is filled with an inert gas, a nitrogen gas, or dry air. Examples of the inert gas include an argon gas, a helium gas, and a xenon gas. The space SP may be in a depressurized atmosphere of 100 Pa or lower.

The base film 12 is separated from each of the thermoelectric element 3 and the bonding portion 7. The base film 12 is not in contact with the thermoelectric element 3. The base film 12 is not in contact with the bonding portion 7.

In the embodiment, the base film 12 is an organic material film. The organic material film is a film made of an organic material. The base film 12 is a thermosetting film made of a synthetic resin material. In the embodiment, the base film 12 is made of an epoxy resin. The base film 12 may be a film containing an epoxy resin as a main component.

The base film 12 may be made of a mixed material of an epoxy resin and another organic material.

The base film 12 is a smooth film. The front surface of the base film 12 is smoother than the front surface of the substrate 2. The front surface of the substrate 2 has a first surface 2A, a second surface 2B, and a third surface 2C. That is, a front surface roughness of the base film 12 is lower than the front surface roughness of the substrate 2.

The base film 12 may have a water vapor barrier property (moisture-proof property). That is, the base film 12 may have a function of preventing dew condensation of the bonding portion 7 and dew condensation of the thermoelectric element 3.

The inorganic material film 13 is a film made of an inorganic material. In the embodiment, the inorganic material film 13 is made of silicon dioxide (SiO₂). The inorganic material film 13 may be a film containing silicon dioxide as a main component. The inorganic material film 13 may be made of a mixed material of silicon dioxide and another inorganic material.

The inorganic material film 13 is disposed so as to cover the front surface of the base film 12. The front surface of the base film 12 has an inner surface 12A facing the space SP between the pair of substrates 2 and an outer surface 12B facing an opposite direction to the inner surface 12A. In the embodiment, the inorganic material film 13 is disposed so as to cover the outer surface 12B of the base film 12. The inorganic material film 13 is in close contact with the outer surface 12B of the base film 12.

The inorganic material film 13 is separated from each of the thermoelectric element 3 and the bonding portion 7. The inorganic material film 13 is not in contact with the thermoelectric element 3. The inorganic material film 13 is not in contact with the bonding portion 7.

The inorganic material film 13 is a water vapor barrier film (moisture-proof film) having a water vapor barrier property (moisture-proof property). The inorganic material film 13 prevents dew condensation of the bonding portion 7 and dew condensation of the thermoelectric element 3.

As described above, the front surface of the base film 12 is smooth. Therefore, the inorganic material film 13 is stably formed on the front surface (outer surface 12B) of the base film 12.

A thickness of the inorganic material film 13 is thinner than a thickness of the base film 12. In the embodiment, the thickness of the base film 12 is approximately 70 [μm]. The thickness of the inorganic material film 13 is approximately equal to or thicker than 0.01 [μm] and equal to or thinner than 1.10 [μm]. As the thickness of the inorganic material film 13 is thicker, the water vapor barrier property of the inorganic material film 13 is improved. In a case where the thickness of the inorganic material film 13 is too thick, a crack is likely to occur in the inorganic material film 13. Therefore, the thickness of the inorganic material film 13 is set based on a required water vapor barrier property and a required crack resistance.

As illustrated in FIG. 6, the thermoelectric module 1 includes a post 10 on which a post electrode 11 is disposed. The post 10 has a columnar shape. A material of the post 10 is nickel (Ni). A material of the post electrode 11 is gold (Au). The post 10 is bonded to the substrate 2 outside the space SP. The post 10 is bonded to the substrate 2 via a bonding portion 70 (second bonding portion). The bonding portion 70 includes an electrode 4 and a bonding layer 5. The bonding portion 70 does not include a diffusion prevention layer 6.

A front surface of the bonding portion 70 between the post 10 and the substrate 2 is covered with the base film 12 and the inorganic material film 13. The base film 12 covers the front surface of the bonding portion 70 between the post 10 and the substrate 2. The inorganic material film 13 covers the base film 12 that covers the front surface of the bonding portion 70 between the post 10 and the substrate 2.

A front surface of the post 10 is covered with the base film 12 and the inorganic material film 13. The base film 12 covers the front surface of the post 10. The inorganic material film 13 covers the base film 12 that covers the front surface of the post 10.

In the example illustrated in FIG. 6, the post 10 is bonded to the first surface 2A of the substrate 2, which is provided in a −Z direction, from the pair of substrates 2 via the bonding portion 70.

The post electrode 11 is disposed at an end portion of the post 10 in the +Z direction.

A plurality of posts 10 are provided at intervals. For example, two posts 10 are provided.

### Method for Manufacturing Thermoelectric Module

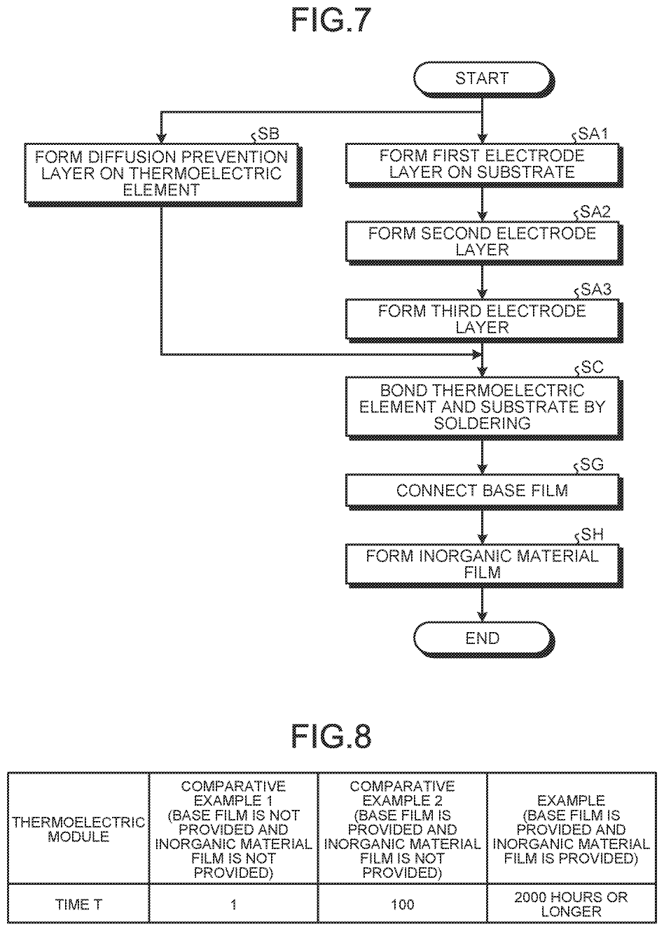

FIG. 7 is a flowchart illustrating a method for manufacturing the thermoelectric module 1 according to the embodiment. As the substrate 2, for example, a substrate made of aluminum nitride (AlN) or aluminum oxide (Al₂O₃) may be used. The first electrode layer 4A made of copper (Cu) is formed on the first surface 2A of the substrate 2. For example, the first electrode layer 4A is formed by plating (step SA1).

Next, the second electrode layer 4B made of nickel (Ni) is formed so as to cover the first electrode layer 4A. For example, the second electrode layer 4B is formed by plating (step SA2).

Next, the third electrode layer 4C made of gold (Au) is formed so as to cover the second electrode layer 4B. For example, the third electrode layer 4C is formed by plating (step SA3).

As described above, an intermediate electrode layer made of palladium (Pd) may be formed between the second electrode layer 4B and the third electrode layer 4C.

The diffusion prevention layer 6 made of nickel (Ni) is formed on the end surface of the thermoelectric element 3. As the thermoelectric element 3, the thermoelectric element 3 made of, for example, a bismuth-tellurium-based compound (Bi—Te) may be used. For example, the diffusion prevention layer 6 is formed by a sputtering method (step SB).

The third electrode layer 4C of the substrate 2 after completion of processing of step SA3 and the diffusion prevention layer 6 of the thermoelectric element 3 after completion of processing of step SB are bonded to each other by the bonding layer 5 which is solder (step SC).

As the bonding layer 5, for example, gold-tin-alloy-based (Au—Sn-based) solder may be used. The substrate 2 and the thermoelectric element 3 are bonded to each other by processing of step SC by the bonding portion 7. The bonding portion 7 includes the electrode 4, the bonding layer 5, and the diffusion prevention layer 6.

Next, the base film 12 is connected to the circumferential edge portions of the pair of substrates 2 (step SG).

As the base film 12, for example, an epoxy resin film for hollow sealing that is manufactured by NAGASE & CO., LTD. may be used. A thickness of the epoxy resin film is, for example, 70 [μm]. By heating the base film 12 in a state of being in contact with the third surface 2C of the substrate 2, the base film 12 is connected to the substrate 2.

Next, the inorganic material film 13 is formed so as to cover the outer surface 12B of the base film 12 (step SH).

For example, the inorganic material film 13 is formed by atomic layer deposition (ALD). Further, the thickness of the inorganic material film 13 is, for example, 0.04 [μm]. The thickness of the inorganic material film 13 may be 0.09 [μm] or 0.14 [μm].

The method for forming the inorganic material film 13 may not be atomic layer deposition, and may be, for example, sputtering, vapor deposition, or chemical vapor deposition (CVD). Preferably, the method for forming the inorganic material film 13 is atomic layer deposition or chemical vapor deposition. According to atomic layer deposition or chemical vapor deposition, even in a case where a front surface of a film to be coated has a complicated shape, it is possible to sufficiently form the film. According to atomic layer deposition, it is possible to form a film at a low temperature as compared with chemical vapor deposition. Thus, atomic layer deposition is excellent in film thickness uniformity and coverage (step coverage) as compared with chemical vapor deposition. Therefore, as the method for forming the inorganic material film 13, preferably, atomic layer deposition is used. Further, in atomic layer deposition, preferably, room-temperature atomic layer deposition (room-temperature ALD) is used. According to room-temperature ALD, it is possible to form a film at room temperature, and thus the thermoelectric module 1 is not damaged by heat. Therefore, preferably, room-temperature ALD is used.

A film may be formed on the second surface 2B of the substrate 2. The film formed on the second surface 2B is unnecessary. For this reason, processing of removing the film formed on the second surface 2B may be performed. In the embodiment, the unnecessary film is removed by laser ablation. A laser beam used for laser ablation is a KrF excimer laser beam (wavelength of 248 [nm]), and oxygen (O₂) is used as an assist gas.

### Effects

As described above, according to the embodiment, the base film 12 is connected to a circumferential line portion of each of the pair of substrates 2, and thus the space SP between the pair of substrates 2 is sealed. The front surface (outer surface 12B) of the base film 12 is smoother than the front surface of the substrate 2. The inorganic material film 13 is formed on the smooth front surface of the base film 12, and thus an occurrence of a crack in the inorganic material film 13 is prevented. The base film 12 is covered with the inorganic material film 13 in which an occurrence of a crack is prevented, and thus water vapor (moisture) is prevented from entering into the space SP between the pair of substrates 2. As a result, dew condensation of the bonding portion 7 and dew condensation of the thermoelectric element 3 are prevented, the bonding portion 7 and the thermoelectric element 3 being disposed in the space SP defined by the pair of substrates 2 and the base film 12. Thus, even in a case where the bonding portion 7 is energized, an occurrence of electrochemical migration is prevented. Therefore, an occurrence of an electrical short circuit or an electrical disconnection due to movement of the metal of the bonding portion 7 is prevented. Further, a deterioration of the thermoelectric element 3 due to electrochemical migration is prevented. Accordingly, performance of the thermoelectric module 1 is maintained for a long period of time.

In a case where the temperature adjusted by the thermoelectric module 1 is lower than a dew point of an ambient environment atmosphere, dew condensation is highly likely to occur on the thermoelectric module 1. For this reason, in order to prevent an occurrence of electrochemical migration, it is necessary to improve airtightness of the housing (113) and fill an internal space of the housing with an inert gas. In a configuration in which airtightness of the housing is improved and the internal space of the housing is filled with an inert gas, a cost increases. In the embodiment, the space SP in which the bonding portion 7 and the thermoelectric element 3 are disposed is sealed by the base film 12, and the outer surface 12B of the base film 12 is covered with the inorganic material film 13. Therefore, even though airtightness of the housing 113 is low, dew condensation of the bonding portion 7 and dew condensation of the thermoelectric element 3 are sufficiently prevented, and an occurrence of electrochemical migration is prevented. Accordingly, it is possible to provide the thermoelectric module 1 and the optical module 100 with reduced cost.

In the embodiment, the base film 12 is an organic material film. Further, thermal conductivity of the base film 12 is low, and thus a temperature difference between one substrate 2 and the other substrate 2 is prevented from being decreased. Therefore, the Peltier effect of the thermoelectric module 1 is prevented from being reduced. Accordingly, a degradation in performance of the thermoelectric module 1 is prevented.

In the embodiment, the base film 12 is a thermosetting film. Therefore, even in a case where the substrate 2 is heated, softening of the base film 12 and peeling of the base film 12 from the substrate 2 are prevented.

In the embodiment, the base film 12 contains an epoxy resin. By using an epoxy resin, the front surface of the base film 12 is sufficiently smoothed. Further, an epoxy resin has a water vapor barrier property (moisture-proof property). Therefore, dew condensation of the bonding portion 7 and dew condensation of the thermoelectric element 3 are sufficiently prevented.

In the embodiment, the inorganic material film 13 contains silicon dioxide. By using silicon dioxide, the inorganic material film 13 can have a high water vapor barrier property (moisture-proof property). Further, thermal conductivity of silicon dioxide is low, and thus a temperature difference between one substrate 2 and the other substrate 2 is prevented from being decreased. Therefore, the Peltier effect of the thermoelectric module 1 is prevented from being reduced. Accordingly, a degradation in performance of the thermoelectric module 1 is prevented.

A thickness of the inorganic material film 13 is thinner than a thickness of the base film 12. As a result, an excessive increase in the thermal conductivity of the inorganic material film 13 is prevented. Thus, a temperature difference between one substrate 2 and the other substrate 2 is prevented from being decreased. Therefore, the Peltier effect of the thermoelectric module 1 is prevented from being reduced. Accordingly, a degradation in performance of the thermoelectric module 1 is prevented.

The base film 12 is connected to the third surface 2C of the substrate 2. Thus, it is possible to increase a region where the bonding portion 7 is disposed on the first surface 2A. For example, in a case where the base film 12 is connected to the circumferential edge portion of the first surface 2A, a part of the first surface 2A is occupied by the base film 12. As a result, a region where the bonding portion 7 is disposed on the first surface 2A is reduced. By connecting the base film 12 to the third surface 2C of the substrate 2, a region where the bonding portion 7 is disposed on the first surface 2A is increased. Thus, it is possible to connect a large number of thermoelectric elements 3 to the first surface 2A of the substrate 2.

In a case where the space SP in which the thermoelectric element 3 and the bonding portion 7 are disposed is filled with an inert gas or a nitrogen gas, or in a case where the space SP is in a depressurized atmosphere of 100 Pa or lower, electromigration of the metal material due to dew condensation is prevented, and oxidation of the thermoelectric element 3 due to dew condensation is prevented. In a case where the space SP is filled with dry air, electromigration of the metal material due to dew condensation is prevented, and a deterioration of the thermoelectric element 3 due to dew condensation is prevented.

### Example

FIG. 8 is a diagram illustrating a performance test result of the thermoelectric module. A performance test is performed on each of the thermoelectric module 1 according to Example that is manufactured by the above-described manufacturing method, a thermoelectric module according to Comparative Example 1 in which both the base film 12 and the inorganic material film 13 are not provided, and a thermoelectric module according to Comparative Example 2 in which the base film 12 is provided and the inorganic material film 13 is not provided.

In the performance test, in an environment of a high temperature and high humidity (temperature of 85 [° C.] and humidity of 85 [% RH]), a predetermined current is continuously supplied to each of the thermoelectric modules according to Comparative Example 1, Comparative Example 2, and Example, and a time T required until an electric resistance change rate (ΔR), which is a physical quantity for determining a deterioration of the thermoelectric module 1, exceeds 5 [o] is measured.

As illustrated in FIG. 8, the time T according to Comparative Example 1 is one hour, and the time T according to Comparative Example 2 is 100 hours. On the other hand, the time T according to Example is 2000 hours or longer. According to the performance test, it is confirmed that the thermoelectric module 1 according to Example can maintain performance for a long time.

### Modification Example of Second Embodiment

In the above-described embodiment, the base film 12 is made of an epoxy resin. The base film 12 may not be made of an epoxy resin. As a material for forming the base film 12, at least one of polyethylene, ethylene tetrafluoride, polypropylene, cellulose acetate, polyacrylonitrile, polyimide, polysulfone, polyethersulfone, polyamide, polyester, silicone resin, phenol resin, polystyrene, and acrylic resin may be used.

In the above-described embodiment, the inorganic material film 13 is made of silicon dioxide. The inorganic material film 13 may be made of aluminum oxide (AL₂O₃), niobium pentoxide (Nb₂O₅), silicon nitride (Si₃N₄), titanium oxide (TiO₂), or hafnium oxide (HfO₂). In particular, aluminum oxide is excellent in a moisture-proof property (water vapor barrier property).

In the above-described embodiment, the base film 12 is a thermosetting synthetic resin film. The base film 12 may be a thermoplastic synthetic resin film.

In the above-described embodiment, the base film 12 is an organic material film. The base film 12 may be a metal film.

In the above-described embodiment, the inorganic material film 13 is provided on the outer surface 12B of the base film 12. The inorganic material film 13 may be provided on each of the inner surface 12A and the outer surface 12B of the base film 12.

In the above-described embodiment, the base film 12 is connected to the third surface 2C of the substrate 2. The base film 12 may be connected to the first surface 2A of the substrate 2.

In the above-described embodiment, the thermoelectric module 1 absorbs heat or generates heat by the Peltier effect. The thermoelectric module 1 may generate electric power by the Zeebeck effect. In a case where a temperature difference is given to the pair of substrates 2 of the thermoelectric module 1, the thermoelectric module 1 can generate electric power by the Zeebeck effect.

In the above-described embodiment, the front surface of the post 10 is covered with the base film 12 and the inorganic material film 13. At least a part of the front surface of the post 10 may be separated from the base film 12 and the inorganic material film 13.

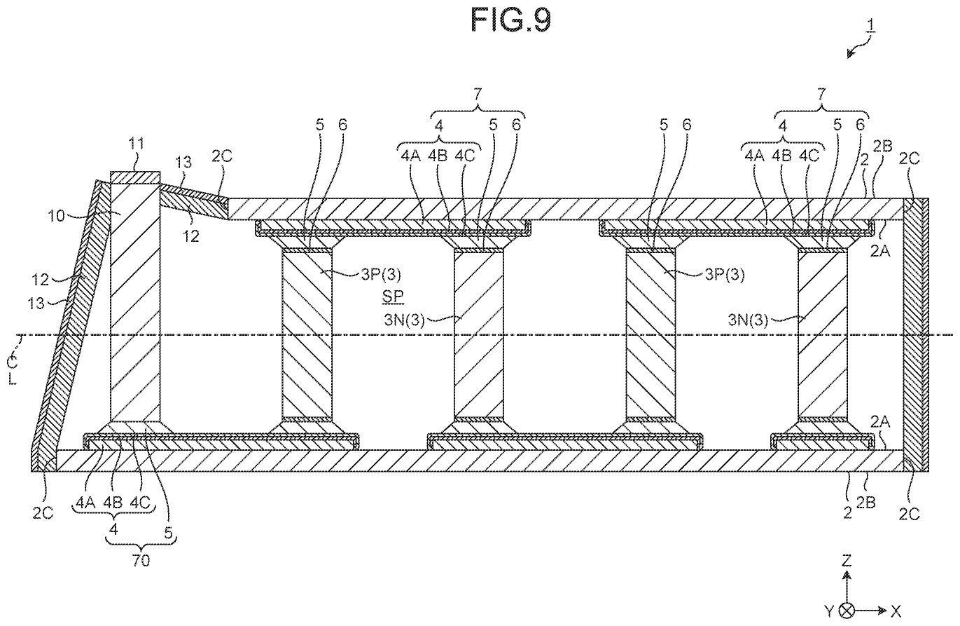

FIG. 9 is a sectional view illustrating a first modification example of the thermoelectric module 1 according to the embodiment. As illustrated in FIG. 9, a part of the front surface of the post 10 is separated from the base film 12. In the example illustrated in FIG. 9, the base film 12 is connected to the third surface 2C of the substrate 2. The inorganic material film 13 is disposed so as to cover the base film 12. At least a part of the post 10 is disposed in the space SP defined by the pair of substrates 2 and the base film 12. The post electrode 11 which is disposed at an end portion of the post 10 in the +Z direction is disposed outside the space SP.

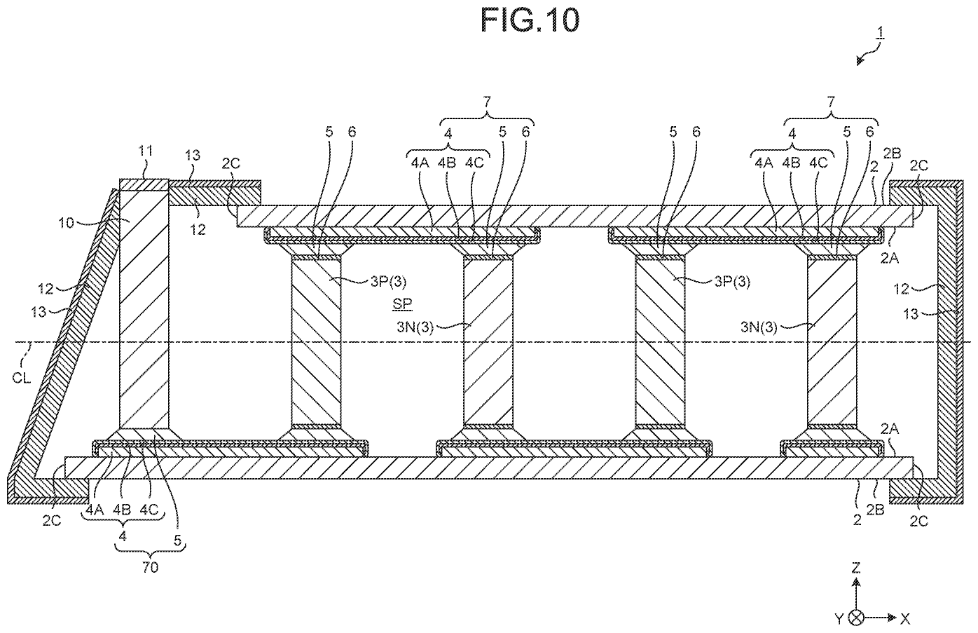

FIG. 10 is a sectional view illustrating a second modification example of the thermoelectric module 1 according to the embodiment. As illustrated in FIG. 10, a part of the front surface of the post 10 is separated from the base film 12. In the example illustrated in FIG. 10, the base film 12 is connected to the second surface 2B of the substrate 2. The inorganic material film 13 is disposed so as to cover the base film 12. At least a part of the post 10 is disposed in the space SP defined by the pair of substrates 2 and the base film 12. The post electrode 11 which is disposed at an end portion of the post 10 in the +Z direction is disposed outside the space SP.

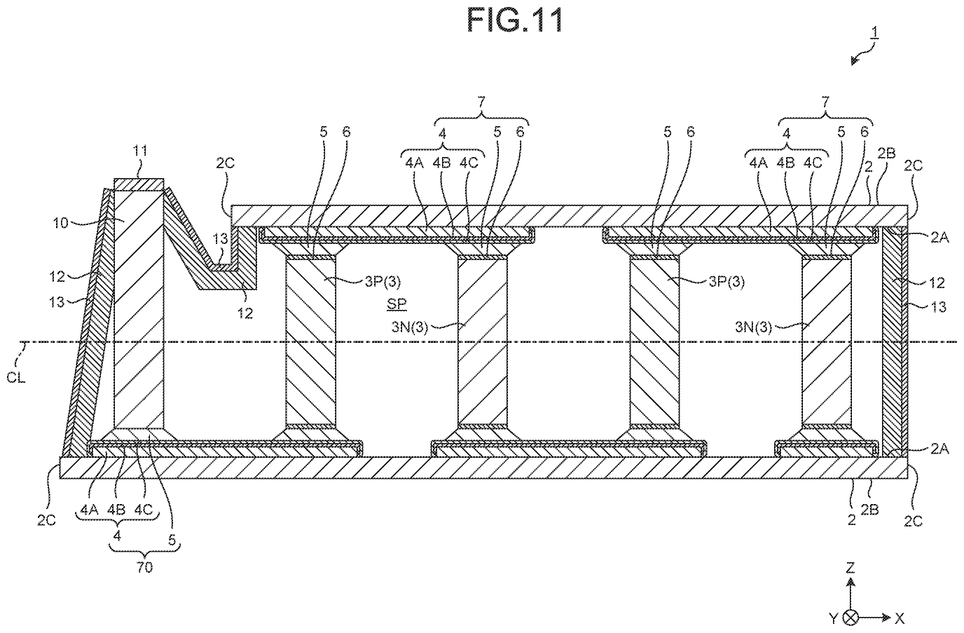

FIG. 11 is a sectional view illustrating a third modification example of the thermoelectric module 1 according to the embodiment. As illustrated in FIG. 11, a part of the front surface of the post 10 is separated from the base film 12. In the example illustrated in FIG. 11, the base film 12 is connected to the first surface 2A of the substrate 2. The inorganic material film 13 is disposed so as to cover the base film 12. At least a part of the post 10 is disposed in the space SP defined by the pair of substrates 2 and the base film 12. The post electrode 11 which is disposed at an end portion of the post 10 in the +Z direction is disposed outside the space SP.

### REFERENCE SIGNS LIST

1 THERMOELECTRIC MODULE

2 SUBSTRATE

2A FIRST SURFACE

2B SECOND SURFACE

2C THIRD SURFACE

3 THERMOELECTRIC ELEMENT

3N FIRST THERMOELECTRIC ELEMENT

3P SECOND THERMOELECTRIC ELEMENT

4 ELECTRODE

4A FIRST ELECTRODE LAYER

4B SECOND ELECTRODE LAYER

4C THIRD ELECTRODE LAYER

5 BONDING LAYER

6 DIFFUSION PREVENTION LAYER

7 BONDING PORTION

8 ORGANIC MATERIAL FILM

9 INORGANIC MATERIAL FILM

10 POST

11 POST ELECTRODE

12 BASE FILM

12A INNER SURFACE

12B OUTER SURFACE

13 INORGANIC MATERIAL FILM

70 BONDING PORTION (SECOND BONDING PORTION)

100 OPTICAL MODULE

101 LIGHT EMITTING ELEMENT

102 HEAT SINK

103 FIRST HEADER

104 LIGHT RECEIVING ELEMENT

105 SECOND HEADER

106 TEMPERATURE SENSOR

107 METAL PLATE

108 LENS

109 LENS HOLDER

110 FIRST TERMINAL

111 SECOND TERMINAL

112 WIRE

113 HOUSING

114 OPENING

115 OPTICAL ISOLATOR

116 OPTICAL FERRULE

117 OPTICAL FIBER

118 SLEEVE

CL SYMMETRY LINE

SP SPACE

1. A thermoelectric module comprising:
a substrate;
a thermoelectric element;
a bonding portion including an electrode that bonds the substrate and the thermoelectric element;
an organic material film that covers a front surface of the bonding portion; and
an inorganic material film that covers the organic material film.

2. The thermoelectric module according to claim 1, wherein the organic material film contains polyparaxylylene, and
the inorganic material film contains silicon dioxide.

3. The thermoelectric module according to claim 1,
wherein the bonding portion includes a diffusion prevention layer formed of nickel.

4. The thermoelectric module according to claim 1,
wherein a thickness of the inorganic material film is thinner than a thickness of the organic material film.

5. The thermoelectric module according to claim 1,
wherein a front surface of the thermoelectric element is covered with the organic material film, and
the organic material film that covers the front surface of the thermoelectric element is covered with the inorganic material film.

6. The thermoelectric module according to claim 1, further comprising:
a post on which a post electrode is provided,
wherein the post is bonded to the substrate via a second bonding portion.

7. The thermoelectric module according to claim 6,
wherein a front surface of the second bonding portion between the post and the substrate is covered with the organic material film and the inorganic material film.

8. The thermoelectric module according to claim 7,
wherein a front surface of the post is covered with the organic material film and the inorganic material film.

9. A thermoelectric module comprising:
a pair of substrates;
a thermoelectric element disposed between the pair of substrates;
a base film that is connected to circumferential line portions of the substrates and seals a space between the pair of substrates; and
an inorganic material film that covers a front surface of the base film.

10. The thermoelectric module according to claim 9,
wherein the base film is an organic material film.

11. The thermoelectric module according to claim 10,
wherein the organic material film is a thermosetting film.

12. The thermoelectric module according to claim 10,
wherein the organic material film contains an epoxy resin, and
the inorganic material film contains silicon dioxide.

13. The thermoelectric module according to claim 9,
wherein a thickness of the inorganic material film is thinner than a thickness of the base film.

14. The thermoelectric module according to claim 9,
wherein the substrate has a first surface facing a space between the pair of substrates, a second surface facing an opposite direction to the first surface, and a third surface that connects a circumferential edge portion of the first surface and a circumferential edge portion of the second surface, and
the base film is connected to the third surface.

15. The thermoelectric module according to claim 14, further comprising:
a bonding portion including an electrode that bonds the first surface of the substrate and the thermoelectric element,
wherein the bonding portion includes a diffusion prevention layer formed of nickel.

16. The thermoelectric module according to claim 14,
wherein the space is filled with an inert gas, nitrogen gas, or dry air.

17. The thermoelectric module according to claim 14,
wherein the space is in a depressurized atmosphere.

18. The thermoelectric module according to claim 9, further comprising:
a post on which a post electrode is provided,
wherein the post is bonded to the substrate via a second bonding portion.

19. The thermoelectric module according to claim 18,
wherein a front surface of the second bonding portion between the post and the substrate is covered with the base film and the inorganic material film.

20. The thermoelectric module according to claim 19,
wherein a front surface of the post is covered with the base film and the inorganic material film.

21. An optical module comprising:
the thermoelectric module according to claim 1; and
a light emitting element of which a temperature is adjusted by the thermoelectric module.
